(19) United States
(12) Patent Application Publication
(10) Pub. No.: US 2026/0033007 A1
(43) Pub. Date: Jan. 29, 2026

(54) DISPLAY DEVICE AND ELECTRONIC DEVICE INCLUDING THE SAME

(71) Applicant: Samsung Display Co., LTD., Yongin-si (KR)

(72) Inventors: Jin Sung AN, Yongin-si (KR); Se Wan SON, Yongin-si (KR); Sung Ho KIM, Yongin-si (KR)

(21) Appl. No.: 19/031,805

(22) Filed: Jan. 18, 2025

(30) Foreign Application Priority Data
Jul. 29, 2024 (KR) 10-2024-0100463

(51) Int. Cl. H10D 86/40; H01L 21/66; H10D 86/60

(52) U.S. Cl. CPC H10D 86/481; H01L 22/32; H10D 86/423; H10D 86/60

(57) ABSTRACT

A display device includes a display panel including a display area in which a plurality of pixels and a plurality of pixel driving circuits which drive each pixel are formed, and a non-display area in which the pixels are not formed, wherein at least one dummy driving circuit unit is formed on one side of the non-display area in a manner of being substantially the same as the pixel driving circuit.

This application claims priority to Korean Patent Application No. 10-2024-0100463, filed on Jul. 29, 2024, and all the benefits accruing therefrom under 35 U.S.C. § 119, the content of which in its entirety is herein incorporated by reference.

### BACKGROUND

### 1. Field

The present invention relates to a display device and an electronic device including the same.

### 2. Description of the Related Art

With the development of multimedia, the importance of a display device is increasing. Along with the increased importance of the display device, interest in an organic light emitting display (OLED) is also increasing due to advantages of wide viewing angle and excellent contrast, as well as fast response speed thereof.

The display device is manufactured through various processes. In order to check whether each process has been properly performed during the manufacturing process of the display device, the thickness, resistance, concentration, degree of contamination, critical dimensions of the resulting product, and electrical characteristics of the elements according to each process may be measured. Meanwhile, as the pixel density (pixels per inch (PPI)) is increased, it is necessary for the display device to reduce a mounting area of a pixel driving circuit or to simplify the driving circuit. In addition, if leakage current occurs in a switching transistor of the pixel driving circuit, brightness of the corresponding pixel may be decreased.

### SUMMARY

According to an aspect of various embodiments of the invention, there is provided a display device in which reliability of a pixel driving circuit is improved, and an electronic device including the same.

According to an embodiment, a display device may comprise a display panel including a display area in which a plurality of pixels and a plurality of pixel driving circuits configured to drive each pixel are formed, and a non-display area in which the pixels are not formed, where at least one dummy driving circuit unit formed on one side of the non-display area in a manner of being substantially the same as the pixel driving circuit.

According to an embodiment, the dummy driving circuit unit may be the same as the pixel driving circuit.

According to an embodiment, the dummy driving circuit unit may include only a part of the pixel driving circuit.

According to an embodiment, the dummy driving circuit unit may include a dummy driving circuit including two transistors and two capacitors (2T2C), and a plurality of test pads which electrically connect the dummy driving circuit with an external test device configured to test whether there is current leakage.

According to an embodiment, the dummy driving circuit may include a driving transistor and a switching transistor, wherein the driving transistor and the switching transistor may be formed of a p-type metal oxide semiconductor (PMOS) based on low temperature poly-silicon (LTPS).

According to an embodiment, the dummy driving circuit may include a driving transistor and a switching transistor, wherein the driving transistor may be formed of a p-type metal oxide semiconductor (PMOS) based on low temperature poly-silicon (LTPS), and wherein the switching transistor may be formed of an n-type metal oxide semiconductor (NMOS) based on oxide.

According to an embodiment, the oxide may include indium gallium zinc oxide (IGZO).

According to an embodiment, the pixels may have a size corresponding to a pixel density (pixels per inch (PPI)) range of about 122 to about 1,696.

According to an embodiment, the pixel driving circuit may include three transistors and two capacitors (3T2C).

According to an embodiment, the pixel driving circuit, and the dummy driving circuit unit may have a configuration in which an active layer ACT and a first gate layer GAT1 are connected through a bridge side contact structure, respectively.

According to an embodiment, an electronic device may comprise a housing and a display device mounted in the housing, wherein the display device includes a display panel including a display area in which a plurality of pixels and a plurality of pixel driving circuits configured to drive each pixel are formed, and a non-display area in which the pixels are not formed, wherein at least one dummy driving circuit unit formed on one side of the non-display area in a manner of being substantially the same as the pixel driving circuit.

### BRIEF DESCRIPTION OF THE DRAWINGS

The above and other objects, features and other advantages of the invention will be more clearly understood from the following detailed description taken in conjunction with the accompanying drawings, in which:

FIG. 1 is a plan view illustrating a display device, according to an embodiment;

FIG. 2A shows a configuration of a pixel driving circuit, according to an embodiment;

FIG. 2B is a cross-sectional view illustrating a laminated structure of the pixel driving circuit, according to an embodiment;

FIG. 3A shows a configuration of a dummy driving circuit, according to an embodiment;

FIG. 3B is a view illustrating a manufacturing process of a dummy driving circuit unit, according to an embodiment;

FIG. 3C is a view illustrating a manufacturing process of the dummy driving circuit unit, according to an embodiment;

FIG. 3D is a view illustrating a manufacturing process of the dummy driving circuit unit, according to an embodiment;

FIG. 3E is a view illustrating a manufacturing process of the dummy driving circuit unit, according to an embodiment;

FIG. 4A shows a configuration of a dummy driving circuit, according to another embodiment;

FIG. 4B is a view of a dummy driving circuit unit, according to another embodiment;

FIG. 4C is a view illustrating a manufacturing process of the dummy driving circuit unit, according to another embodiment;

FIG. 4D is a view illustrating a manufacturing process of the dummy driving circuit unit, according to another embodiment;

FIG. 4E is a view illustrating a manufacturing process of the dummy driving circuit unit, according to another embodiment;

FIG. 5 is a plan view illustrating a display device, according to another embodiment; and

FIG. 6 is a view illustrating an electronic device, according to an embodiment.

### DETAILED DESCRIPTION

Hereinafter, various embodiments of the invention will be described with reference to the accompanying drawings. Specific embodiments of the invention will be illustrated in the drawings and described in the following detailed description related thereto, but it is not intended to limit the various embodiments to a specific form. For example, it will be obvious to those skilled in the art to which the invention pertains that the embodiments may be variously modified.

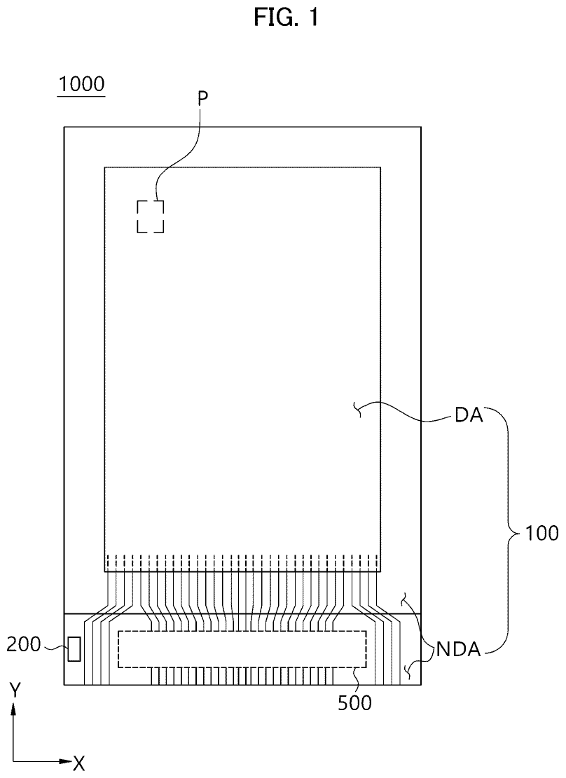

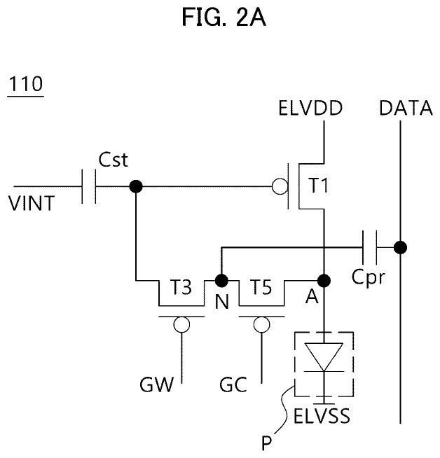

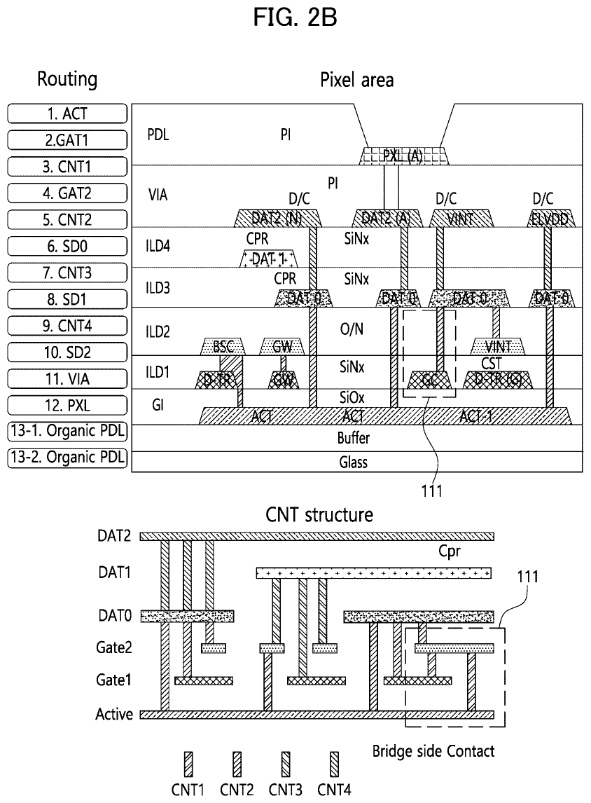

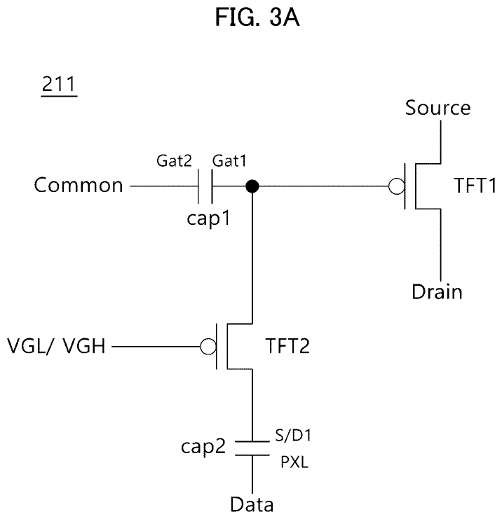

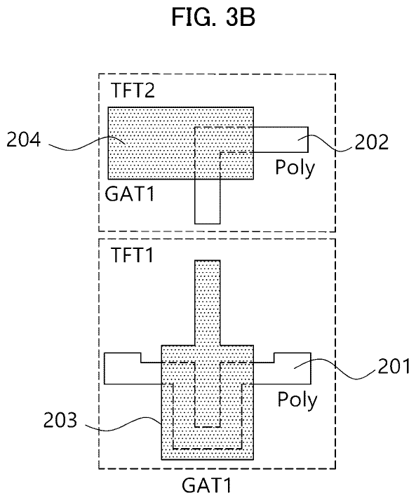

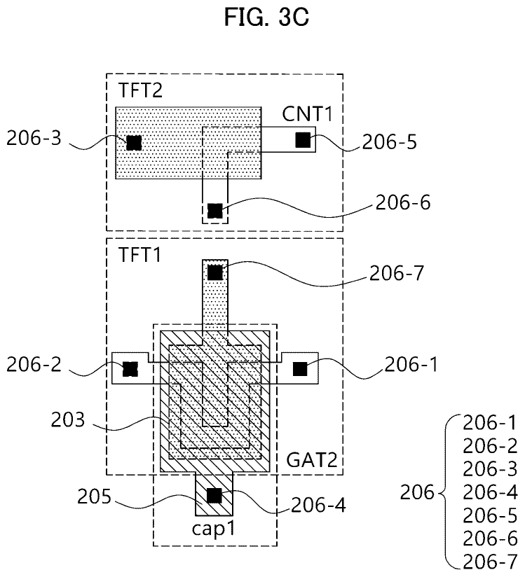

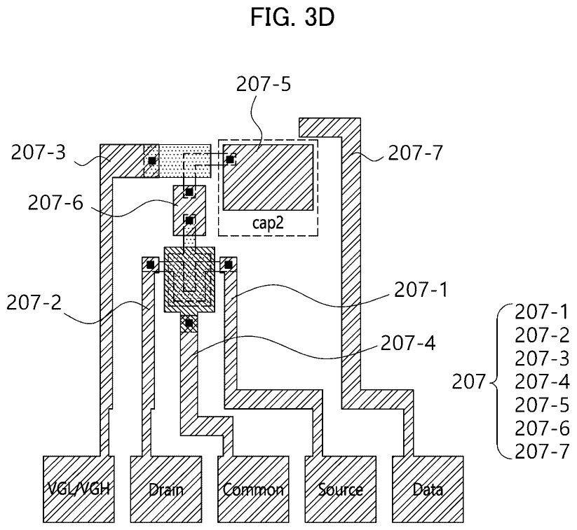

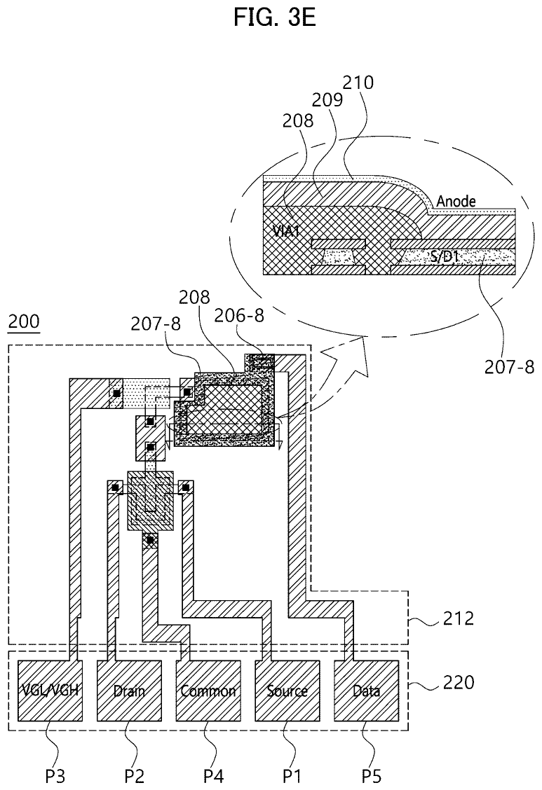

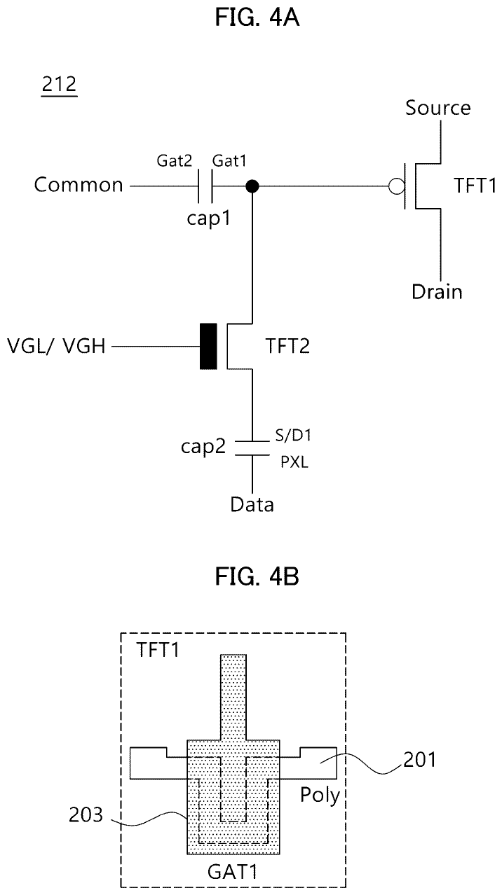

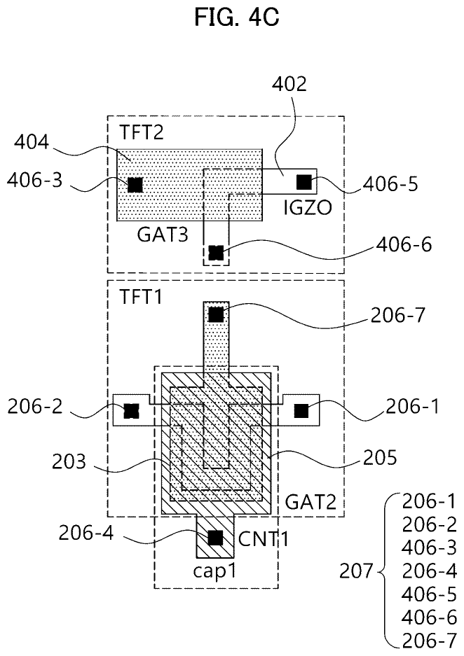

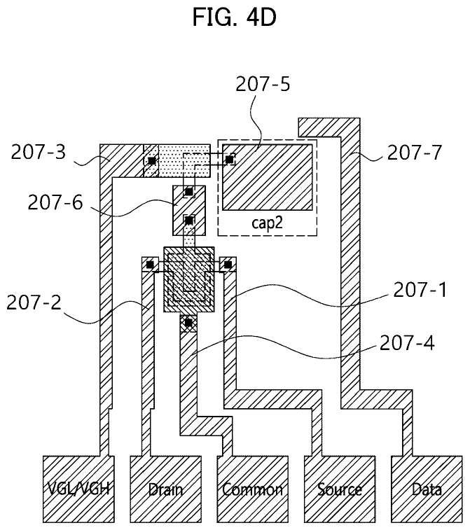

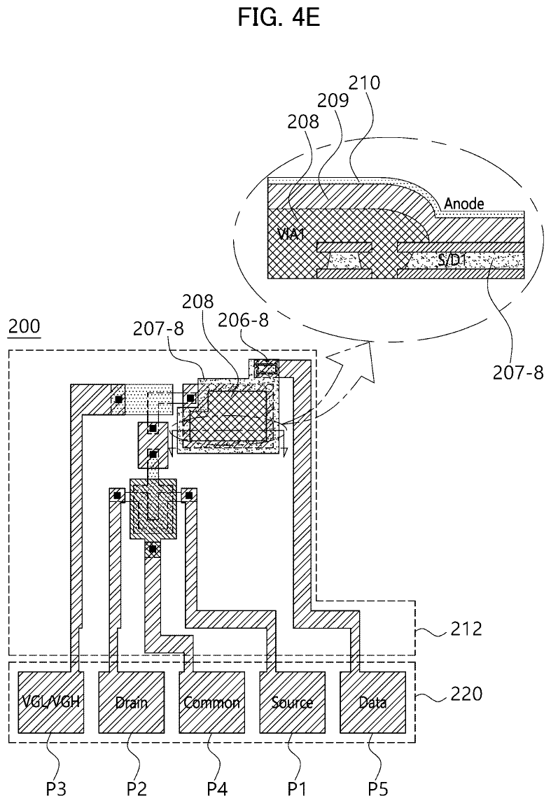

FIG. 1 is a view illustrating a display device, according to an embodiment, FIG. 2A is a view illustrating a configuration of a pixel driving circuit, according to an embodiment, FIG. 2B is a cross-sectional view illustrating a laminated structure of the pixel driving circuit, according to an embodiment, FIG. 3A is a view illustrating a configuration of a dummy driving circuit, according to an embodiment, FIGS. 3B to 3E are views illustrating manufacturing processes of a dummy driving circuit unit, according to an embodiment, FIG. 4A is a view illustrating a configuration of a dummy driving circuit, according to another embodiment, and FIGS. 4B to 4E are views illustrating manufacturing processes of a dummy driving circuit unit, according to another embodiment.

Referring to FIGS. 1 to 4E, a display device 1000, according to an embodiment may include a display panel 100, a dummy driving circuit unit 200 and a driving element 500.

In an embodiment, the display panel 100 may be formed of various materials. For example, the display panel 100 may be made of an inorganic material such as glass, a metallic material, an organic material such as plastic, a resin and the like. The display panel 100 may be transparent or opaque. The display panel 100 may be formed of a rigid or flexible material.

In an embodiment, the display panel 100 may include a display area DA and a non-display area NDA.

The display area DA may display images (e.g., still images or moving images). In an embodiment, in the display area DA, a plurality of pixels P and a pixel driving circuit 110 for driving each pixel may be formed.

In an embodiment, the pixel P is a minimum unit for displaying an image, and may be an organic light-emitting element. However, this is merely an example, and does not limit the invention. For example, the pixel P may be an electrophoretic display element. The pixel P may have a small size in order to support high resolution in the portable display device 1000 having a relatively small size (e.g., about 7 inches or less). For example, the pixels P may have a size corresponding to a pixel density (pixels per inch (PPI)) in a designated range (e.g., “about 122 to about 1,696”).

In an embodiment, as the pixel density PPI of the display device 1000 is increased, the pixel driving circuit 110 may include three thin film transistors T1, T3 and T5, and two capacitors Cst and Cpr, as shown in FIG. 2A. Hereinafter, the structure of the pixel driving circuit 110 will be expressed as 3T2C. The pixel driving circuit 110 may be formed in a laminated structure, as shown in FIG. 2B and may have a bridge side contact structure 111 as a contact CNT structure of an active layer ACT and a first gate layer GAT1. All currents of the programming capacitor Cpr may not be completely provided to a switching transistor T3, and some of them may leak. When the leakage current occurs, brightness of the pixel may be decreased. However, display devices currently known in the art do not provide a means for checking whether a leakage current occurs in the switching transistor T3 of the pixel driving circuit 110 and/or the magnitude of the leakage current.

In an embodiment, the non-display areas NDA are formed around the display area DA, and the pixels may not be formed therein. For example, the non-display area NDA may be formed on a lower side of the display area DA, as shown in FIG. 1. In addition, the non-display areas NDA may be formed on upper, left and/or right sides of the display area DA.

According to an embodiment, the non-display area NDA may include a driving element 500 configured to control driving of the display area DA and at least one dummy driving circuit unit (which may be referred to as a test element group (TEG)) 200.

In an embodiment, the driving element 500 may control driving of the pixels P included in the display area DA. The driving element 500 may receive a driving signal for driving the pixels of the display area DA from an outside through a flexible printed circuit board (FPCB), and supply the received driving signal to the pixels of the display area DA. For example, as shown in FIG. 2A, the driving signal may include a driving power ELVDD, a common power ELVSS, an initialization signal VINT, a scan signal GW, a data signal DATA, a compensation signal GC and the like.

In an embodiment, the dummy driving circuit unit 200 may be formed separately in the non-display area NDA to check (measure) whether the pixel driving circuit 110 is defective (e.g., whether there is current leakage). The dummy driving circuit unit 200 may include dummy driving circuits 211 and 212, and a test pad 220.

In an embodiment, the dummy driving circuits 211 and 212 may be substantially the same as the pixel driving circuit 110. For example, the dummy driving circuits 211 and 212 may have the 2T2C structure, as shown in FIGS. 3A and 4A, by removing a compensation capacitor T5, which is not related to the leakage current in the pixel driving circuit 110. A driving transistor TFT1 of each of the dummy driving circuits 211 and 212 may correspond to the driving transistor T1 of the pixel driving circuit 110, and a switching transistor TFT2 of each of the dummy driving circuits 211 and 212 may correspond to the switching transistor T3 of the pixel driving circuit 110. The dummy driving circuits 211 and 212 may have a configuration in which the active layer ACT and the first gate layer GAT1 are connected through the bridge side contact structure in the same manner as the pixel driving circuit 110.

The dummy driving circuit 211 (hereinafter, referred to as a first dummy driving circuit) shown in FIG. 3A illustrates an example in which the driving transistor TFT1 and the switching transistor TFT2 are formed of a p-type metal oxide semiconductor (PMOS) based on low temperature poly-silicon (LTPS). Here, a manufacturing process of the first dummy driving circuit 211 will be briefly described with reference to FIGS. 3B to 3E.

In an embodiment and referring to FIG. 3B, a first active pattern 201 for the driving transistor TFT1 and a second active pattern 202 for the switching transistor TFT2 may be formed through an active patterning process for patterning an active layer based on low temperature poly-silicon (LTPS).

In addition, a first-1 gate pattern 203 for the driving transistor TFT1 and a first-2 gate pattern 204 for the switching transistor TFT2 may be formed through a first gate patterning process for patterning the first gate layer GAT1. Meanwhile, for the convenience of description, the active patterning process and the first gate patterning process will not be described in detail. In addition, although not shown in FIG. 3B, a first gate insulator (GI) formation (e.g., deposition) process may be performed after the active patterning process.

In an embodiment and referring to FIG. 3C, a second gate pattern 205 may be formed through a second gate patterning process for patterning a second gate layer GAT2. The first-1 gate pattern 203 and the second gate pattern 205 may operate as a first capacitor cap1. Meanwhile, the second gate patterning process will not be described in detail. In addition, although not shown in FIG. 3C, a source-drain doping process and a second gate insulation film GI formation process may be performed before the second gate patterning process.

In addition, in an embodiment, a plurality of CNTs 206 may be formed through a primary CNT patterning process, where the plurality of CNTs 206 may connect the first active pattern 201, the second active pattern 202, the first-1 gate pattern 203, the first-2 gate pattern 204, and/or the second gate pattern 205 with a corresponding line pattern among line patterns formed through a primary source-drain patterning process to be described below. According to an embodiment, the plurality of CNTs 206 may include a first CNT 206-1 for connection with a source electrode of the driving transistor TFT1, a second CNT 206-2 for connection with a drain electrode of the driving transistor TFT1, a third CNT 206-3 for connection with a gate electrode of the switching transistor TFT2, a fourth CNT 206-4 for connection with one side of the first capacitor cap1, a fifth CNT 206-5 for connection with a drain electrode of the switching transistor TFT2, a sixth CNT 206-6 for connection with a source electrode of the switching transistor TFT2, and a seventh CNT 206-7 for connection with a gate electrode of the driving transistor TFT1. Here, the CNT patterning process will not be described in detail.

In an embodiment and referring to FIG. 3D, a plurality of line patterns 207 may be formed through the primary source-drain patterning process. According to an embodiment, the plurality of line patterns 207 may include a first line pattern 207-1 for connecting a source of the driving transistor TFT1 with a first metal pad P1 among test pads 220 to be described below, a second line pattern 207-2 for connecting a drain of the driving transistor TFT1 with a second metal pad P2, a third line pattern 207-3 for connecting a gate of the switching transistor TFT2 with a third metal pad P3, a fourth line pattern 207-4 for connecting one side of the first capacitor cap1 with a fourth metal pad P4, a fifth line pattern 207-5 connected to a drain of the switching transistor TFT2 and for performing a role of one side electrode of a second capacitor cap2, a sixth line pattern 207-6 for connecting a source of the switching transistor TFT2 with a gate of the driving transistor TFT1, and a seventh line pattern 207-7 for connecting the other side of the second capacitor cap2 with a fifth metal pad P5. Meanwhile, for the convenience of description, the primary source-drain patterning process will not be described in detail.

In an embodiment and referring to FIG. 3E, an eighth CNT 206-8 for connecting the seventh line pattern 207-7 with the other side of the second capacitor cap2 (or an eighth line pattern 207-8 to be described below) may be formed through a primary via hole patterning process. In addition, the eighth line pattern 207-8 may be formed so as to be partially overlapped with the fifth line pattern 207-5 through a secondary source-drain patterning process. The fifth line pattern 207-5 and the eighth line pattern 207-8 may operate as the second capacitor cap2.

In addition, in an embodiment, a via hole 208 may be formed through a secondary via hole patterning process, and an insulation layer 209 and an anode electrode layer 210 of the pixel P may be formed through a pixel patterning process. Meanwhile, the insulation layer 209 covers a part of the eighth line pattern 207-8 and the via hole 208, and the anode electrode layer 210 may be formed on the insulation layer 209. For the convenience of description, the primary via hole patterning process, the secondary source-drain patterning process, and the secondary via hole patterning process will not be described in detail.

In an embodiment, the dummy driving circuit (hereinafter, referred to as a second dummy driving circuit) (212) shown in FIG. 4A illustrates an example in which the switching transistor TFT2 is formed of an n-type metal oxide semiconductor (NMOS) based on oxide. Here, a manufacturing process of the second dummy driving circuit 212 will be briefly described with reference to FIGS. 4B to 4E.

In an embodiment and referring to FIG. 4B, the first active pattern 201 for the driving transistor TFT1 may be formed through a first active patterning process for patterning a first active layer based on low temperature poly-silicon (LTPS), and the first-1 gate pattern 203 for the driving transistor TFT1 may be formed through the first gate patterning process.

In an embodiment and referring to FIG. 4C, the second gate pattern 205 may be formed through the second gate patterning process, where the first-1 gate pattern 203 and the second gate pattern 205 may operate as the first capacitor cap1.

In addition, a second active pattern 402 for the switching transistor TFT2 may be formed through a second active patterning process for patterning a second active layer based on oxide (e.g., indium gallium zinc oxide (IGZO)) formed on the second gate layer. Moreover, a first-2 gate pattern 404 for the switching transistor TFT2 may be formed through a third gate patterning process for patterning a third gate layer GAT3.

Furthermore, some of the plurality of CNTs 206 may be formed through the primary CNT patterning process. For example, the first CNT 206-1 for connection with the source electrode of the driving transistor TFT1, the second CNT 206-2 for connection with the drain electrode of the driving transistor TFT1, the fourth CNT 206-4 for connection with one side of the first capacitor cap1, and the seventh CNT 206-7 for connection with the gate electrode of the driving transistor TFT1 may be formed through the primary CNT patterning process. Also, other some of the plurality of CNTs 206 may be formed through a secondary CNT patterning process. For example, a third CNT 406-3 for connection with the gate electrode of the switching transistor TFT2, a fifth CNT 406-5 for connection with the drain electrode of the switching transistor TFT2, and a sixth CNT 406-6 for connection with the source electrode of the switching transistor TFT2 may be formed through the secondary CNT patterning process.

Through the manufacturing processes shown in FIGS. 4D and 4E, the plurality of line patterns 207-1, 207-2, 207-3, 207-4, 207-5, 207-6, 207-7 and 207-8, the eighth CNT 206-8, the via hole 208, the insulation layer 209 and the anode electrode layer 210 may be formed, according to an embodiment. Here, the procedures of FIGS. 4D and 4E are similar to those of FIGS. 3D and 3E, and therefore will not be described in detail.

The processes for manufacturing the first dummy driving circuit 211 shown in FIGS. 3B to 3E and the second dummy driving circuit 212 of the 2T2C structure shown in FIGS. 4B to 4E are only examples and do not limit the present disclosure. In other words, the manufacturing processes shown in FIGS. 3B to 3E and FIGS. 4B to 4E are schematically illustrated for the convenience of description, and it will be obvious to those skilled in the art that various other processes may be performed before, during, or after performing each manufacturing process. According to an embodiment, the dummy driving circuit may have the same 3T2C structure as the pixel driving circuit 110.

In an embodiment, the test pad 220 may include a plurality of metal pads which come into contact with test pins (e.g., probe pins) of a test device (not shown) configured to test whether the pixel is defective (e.g., detects an occurrence of leakage current through the dummy driving circuit). In addition, the plurality of metal pads of the test pad 220 may be electrically connected to terminals of the dummy driving circuits 211 and 212, respectively. For example, the metal pads of the test pad 220 may be connected to terminals of the dummy driving circuits 211 and 212, respectively, as shown in FIGS. 3E and 4E. Specifically, the test pad 220 may include a first metal pad P1 connected to the source electrode of the driving transistor TFT1, a second metal pad P2 connected to the drain electrode of the driving transistor TFT1, a third metal pad P3 connected to the gate electrode of the switching transistor TFT2, a fourth metal pad P4 connected to the first capacitor cap1, and a fifth metal pad P5 connected to the second capacitor cap2. Here, the test device may measure changes in the leakage current of the switching transistor TFT2 by monitoring a current Ids between the drain terminal and the source terminal of the driving transistor TFT1 via the first metal pad P1 and the second metal pad P2 of the test pad 220.

Additionally, although not shown in FIG. 1, the display device 1000 may further include a plurality of touch electrodes and a touch sensor (e.g. touch IC) on the display panel 100. In addition, the display device 1000 may include two or more dummy driving circuit units 200.

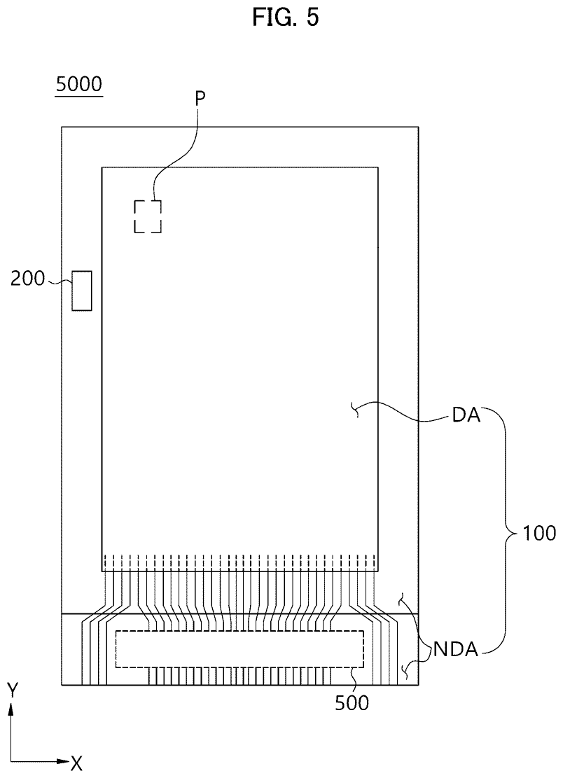

FIG. 5 is a view illustrating a display device, according to another embodiment.

In an embodiment and referring to FIG. 5, a display device 5000 may be similar to the display device 1000 of FIG. 1, except that the location of the dummy driving circuit unit 200 is different therefrom. For example, the dummy driving circuit unit 200 may be formed in the non-display area NDA located on a left side of the display area DA. Here, other configurations or components will not be described in detail.

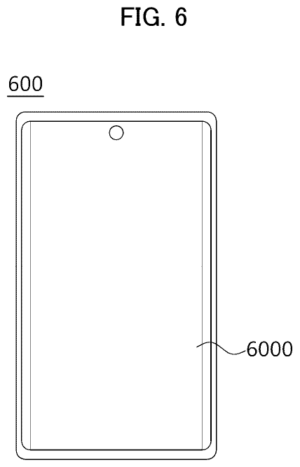

FIG. 6 is a view illustrating an electronic device, according to an embodiment.

In an embodiment and referring to FIG. 6, an electronic device 600 may include various types of electronic devices. For example, the electronic device 600, according to an embodiment, may include a rigid type or flexible type portable communication device (e.g., a smart phone), a computer device, a portable multimedia device, a portable medical device, a camera, a multimedia device installed in, embedded in, or integrally formed with an automobile, or a home appliance device. Meanwhile, the electronic device 600, according to an embodiment, is not limited to the above-described devices and may include more diverse forms of devices.

According to an embodiment, the electronic device 600 may include a display device 6000, where the display device 6000 may be mounted in a housing of the electronic device 600. For example, the display device 6000 may be mounted in the housing so as to be exposed to an outside through a front surface of the electronic device 600. The display device 6000 may provide (e.g., display) various images (e.g., still images or moving images). The display device 6000 may be the same as or similar to the display devices 1000 and 5000 described with reference to FIGS. 1 to 5. Therefore, the display device 6000 will not be described in detail.

In an embodiment, the display device 6000 may further include a touch panel which supports touch input (e.g., finger touch and pen touch). For example, the display device 6000 may include a touch panel (not shown) separately or integrally formed therewith.

Various embodiments of the invention may improve the reliability of the pixel driving circuit. For example, various embodiments of the invention may provide the dummy driving circuit (e.g., the TEG) capable of checking current leakage of the pixel driving circuit (e.g., the switching transistor) on one side of the display panel (e.g., the non-display area of the display panel), and may check the current leakage (or check whether the display device is defective) through the dummy driving circuit. Thereby, through various embodiments, the reliability of the display device may be improved.

In addition, various embodiments may provide a display device with uniform quality. For example, various embodiments may prevent the distribution of a defective display device having relatively low brightness due to the leakage current. In addition, when a defect such as leakage current is detected, the invention may improve manufacturing efficiency of the display device by stopping the manufacturing thereof.

Additionally, various embodiments and the terms used herein do not limit the technical characteristics described in the present disclosure to specific embodiments, and should be construed to include various modifications, equivalents, or replacements of the embodiments. With regard to the description of the drawings, similar or related components may be denoted by similar reference numerals. It is to be understood that a singular form of a noun corresponding to an item may include one or a plurality of the things, unless the relevant context clearly indicates otherwise. As used herein, each of phrases such as “A or B,” “at least one of A and B,” “at least one of A or B,” “A, B or C,” “at least one of A, B and C,” and “at least one of A, B or C” may include any one, or all possible combinations of these items enumerated together in the corresponding one of the phrases. Also, as used herein, the terms such as “1st” and “2nd,” or “first” and “second” may be used to simply distinguish the corresponding component from another component, and does not limit the corresponding components in other aspects (e.g., an importance or order). It is to be understood that if a component (e.g., a first component) is referred to as “coupled to” or “connected to” another component (e.g., a second component), with or without the term “operatively” or “communicatively,” it means that the component may be coupled to the other component directly (e.g., by wire), wirelessly, or via a third component.

Additionally, the term “module” used in various embodiments may include a unit implemented in hardware, software or firmware way, and for example, may be used interchangeably with the terms such as logic, a logic block, a part, or a circuit. The module may be a part integrally formed therewith, or a minimum unit of the part or a portion thereof which performs one or more functions. For example, according to an embodiment, the module may be implemented in a form of an application-specific integrated circuit (ASIC).

Various embodiments may be implemented by software (e.g., a program) including one or more instructions stored in a storage medium (e.g., an internal memory or an external memory) readable by a machine (e.g., an electronic device 600). For example, a processor of the machine (e.g., the electronic device 600) may call, among one or more instructions stored in the storage medium, at least one instruction, and may execute the instruction. This allows at least one function to be performed according to the called at least one instruction. The one or more instructions may include a code that is made by a compiler or a code that may be executed by an interpreter. The storage medium that may be read by a device may be provided in a form of a ‘non-transitory storage medium’. Here, the ‘non-transitory storage medium’ means that the storage medium is a tangible device and does not include a signal (e.g., an electromagnetic wave), and with regard to the term, a case, in which data are semi-permanently stored in the storage medium, and a case, in which data are temporarily stored in the storage medium, are not distinguished.

The methods according to various embodiments may be provided to be included in a computer program product. The computer program product may be traded between a seller and a purchaser. The computer program product may be distributed in a form of a storage medium that may be read by a device (e.g., a compact disk read only memory (CD-ROM)) or that may be distributed (e.g., downloaded or uploaded) through an application store or directly or online between two user devices. In the online distribution, at least a portion of the computer program product may be at least temporarily stored in a storage medium, such as a server of a manufacturer, a server of an application store, or a memory of a relay server, which may be read by a device, or temporarily generated.

According to various embodiments, each component or element (e.g., a module or program) of the above-described components or elements may include one or a plurality of entities, and some of the plurality of entities may be disposed related to other components while being separated therefrom. According to various embodiments, among the above-described components, one or more components or operations thereof may be omitted or one or more other components or operations thereof may be added to the components. In another embodiment, the plurality of components (e.g., the modules or programs) may be integrated into one component. In this case, the integrated components may perform one or more functions of each component of the plurality of components in a way that they are the same as or similar to the functions performed by the corresponding components among the plurality of components before the integration. According to various embodiments, operations performed by the modules, programs, or other components may be executed sequentially, in parallel, repeatedly, or heuristically, one or more operations may be executed in another sequence or omitted, or one or more other operations may be added thereto.

It will be understood by one of ordinary skill in the art to which the invention belongs that the invention may be implemented in other specific embodiments than those described herein without changing the technical spirit or essential features of the invention. Therefore, it is to be understood that the exemplary embodiments described above are illustrative rather than being restrictive in all aspects. The disclosed embodiments of the invention are used in a generic and descriptive sense only and not for purposes of limitation. Each component specifically shown in the embodiments of the invention can be implemented by modification, and such modifications and differences related to invention should be construed as being included in the scope of the invention. Moreover, the embodiments or parts of the embodiments may be combined in whole or in part without departing from the scope of the invention.

What is claimed is:

1. A display device comprising:
a display panel including a display area in which a plurality of pixels and a plurality of pixel driving circuits which drive each pixel are formed, and a non-display area in which the pixels are not formed; wherein
at least one dummy driving circuit unit formed on one side of the non-display area in a manner of being substantially the same as the pixel driving circuit.

2. The display device according to claim 1, wherein the dummy driving circuit unit is the same as the pixel driving circuit.

3. The display device according to claim 1, wherein the dummy driving circuit unit includes only a part of the pixel driving circuit.

4. The display device according to claim 3, wherein the dummy driving circuit unit comprises:
a dummy driving circuit including two transistors and two capacitors (2T2C); and
a plurality of test pads which electrically connect the dummy driving circuit with an external test device which tests whether there is current leakage.

5. The display device according to claim 4, wherein the dummy driving circuit comprises a driving transistor and a switching transistor,
wherein the driving transistor and the switching transistor are formed of a p-type metal oxide semiconductor (PMOS) based on low temperature poly-silicon (LTPS).

6. The display device according to claim 4, wherein the dummy driving circuit comprises a driving transistor and a switching transistor,
wherein the driving transistor is formed of a p-type metal oxide semiconductor (PMOS) based on low temperature poly-silicon (LTPS), and
wherein the switching transistor is formed of an n-type metal oxide semiconductor (NMOS) based on oxide.

7. The display device according to claim 6, wherein the oxide includes indium gallium zinc oxide (IGZO).

8. The display device according to claim 1, wherein the pixels have a size corresponding to a pixel density (pixels per inch (PPI)) range of about 122 to about 1,696.

9. The display device according to claim 1, wherein the pixel driving circuit comprises three transistors and two capacitors (3T2C).

10. The display device according to claim 1, wherein the pixel driving circuit and the dummy driving circuit unit have a configuration in which an active layer ACT and a first gate layer GAT1 are connected through a bridge side contact structure, respectively.

11. An electronic device comprising:
a housing; and
a display device mounted in the housing,
wherein the display device comprises:
a display panel including a display area in which a plurality of pixels and a plurality of pixel driving circuits which drive each pixel are formed, and a non-display area in which the pixels are not formed; wherein
at least one dummy driving circuit unit is formed on one side of the non-display area in a manner of being substantially the same as the pixel driving circuit.

12. The electronic device according to claim 11, wherein the dummy driving circuit unit is the same as the pixel driving circuit.

13. The electronic device according to claim 11, wherein the dummy driving circuit unit includes only a part of the pixel driving circuit.

14. The electronic device according to claim 13, wherein the dummy driving circuit unit comprises:
a dummy driving circuit including two transistors and two capacitors (2T2C); and
a plurality of test pads which electrically connect the dummy driving circuit with an external test device which tests whether there is current leakage.

15. The electronic device according to claim 14, wherein the dummy driving circuit comprises a driving transistor and a switching transistor,
wherein the driving transistor and the switching transistor are formed of a p-type metal oxide semiconductor (PMOS) based on low temperature poly-silicon (LTPS).

16. The electronic device according to claim 14, wherein the dummy driving circuit comprises a driving transistor and a switching transistor,
wherein the driving transistor is formed of a p-type metal oxide semiconductor (PMOS) based on low temperature poly-silicon (LTPS), and
wherein the switching transistor is formed of an n-type metal oxide semiconductor (NMOS) based on oxide.

17. The electronic device according to claim 16, wherein the oxide includes indium gallium zinc oxide (IGZO).

18. The electronic device according to claim 11, wherein the pixels have a size corresponding to a pixel density (pixels per inch (PPI)) range of about 122 to about 1,696.

19. The electronic device according to claim 11, wherein the pixel driving circuit comprises three transistors and two capacitors (3T2C).

20. The electronic device according to claim 11, wherein the pixel driving circuit and the dummy driving circuit unit have a configuration in which an active layer ACT and a first gate layer GAT1 are connected through a bridge side contact structure, respectively.
